(19) United States
(12) Patent Application Publication
(10) Pub. No.: US 2009/0060692 A1
(43) Pub. Date: Mar. 5, 2009

(54) SUBSTRATE POSITIONAL MISALIGNMENT DETECTION SYSTEM

(75) Inventor: Shinji WAKABAYASHI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/200,054

(22) Filed: Aug. 28, 2008

Related U.S. Application Data
(60) Provisional application No. 60/991,818, filed on Dec. 3, 2007.

(30) Foreign Application Priority Data
Sep. 4, 2007 (JP) 2007-228939

(51) Int. Cl. H01L 21/67

(52) U.S. Cl. 414/222.02

(57) ABSTRACT

A substrate positional misalignment detection system capable of detecting positional misalignment of a substrate without moving a detector in the case of using a bottom opening pod having a main body, a lid and a cassette holding wafers. A recursive reflection type sensor adapted to emit and receive light in an upward/downward direction is provided in a supporting unit adapted to support the lid and move up and down the lid together with the cassette. A recursive reflection plate adapted to reflect the emitted light is provided on the ceiling portion of the main body. A light transmitting window is provided in the lid. The recursive reflection type sensor, the light transmitting window, and the recursive reflection plate are aligned linearly in the upward/downward direction. The light emitted by the recursive reflection type sensor is not blocked by the substrate held in a predetermined storage position by the cassette.

### BACKGROUND OF THE INVENTION

1. Field of the Invention

The present invention relates to a substrate positional misalignment detection system, and in particular to a substrate positional misalignment detection system for optically detecting positional misalignment of a substrate.

2. Description of the Related Art

In general, in order to effectively process a plurality of substrates, a substrate processing system for processing a semiconductor wafer (hereinafter referred to as “wafer”) as a substrate is provided with a processing device for processing the plurality of wafers and a transfer device for transferring the wafers from a container storing the wafers in an aligned state to the processing device.

The container is a box having an opening allowing a wafer to be loaded and unloaded therethrough and has therein a plurality of groove-shaped slots to hold a peripheral edge part of a wafer and capable of storing the wafer perpendicular to the plane on which the opening is provided. Moreover, the container stores a plurality of wafers in predetermined internal storage positions by inserting the wafers into the individual slots in a state in which the wafers are aligned parallel to each other. The transfer device transfers the wafers stored in a predetermined storage position of the container one by one or in a batch to the processing device, which performs various processes on the wafer.

However, the above described substrate processing system may cause a wafer to be shifted from the predetermined storage position due to a vibration added to the container or the like. When the wafer is shifted from the predetermined storage position, the transfer device fetches the wafer from the container as being shifted from the predetermined storage position, and thus the wafer is transferred on an unexpected path. As a result, the wafer may be damaged by colliding with other components of the substrate processing system. In order to prevent such wafer damage, it is necessary to confirm the presence or absence of positional misalignment of a wafer in the container before the wafer is transferred.

As a wafer positional misalignment detector, there has been known a detector 30 detecting a slip-out state where a wafer is shifted from a predetermined storage position of the container up to in front of the opening thereof as shown in FIG. 7 (see e.g. Japanese Laid-Open Patent Publication (Kokai) No. 2003-100852). The detector 30 is provided with a light emitting unit 32 and a light receiving unit 33 which are installed in front of the opening of the container 31, at the upper and lower portions of the container 31 respectively and which constitute a light transmission type sensor. The detector 30 emits light from the light emitting unit 32 to the light receiving unit 33 and detects a slip-out of a wafer W by detecting whether the emitted light is blocked by the slipped-out wafer W.

As another wafer positional misalignment detector, there has also been known a detector detecting a jump slot state where the individual wafers are not correctly inserted into the individual slots, and thus the container stores more than or less than a predetermined number of wafers (see e.g. Japanese Laid-Open Patent Publication (Kokai) No. 07-147316).

In addition, as a next generation container, there has been considered a bottom opening pod (hereinafter referred to as “BOP”) having an approximately box-shaped main body having an opening at the bottom surface and a plate-like lid capable of opening and closing the opening. The BOP contains a cassette for holding a plurality of wafers. The cassette is a frame having a plurality of groove-shaped slots arranged parallel to each other for holding a peripheral edge of a wafer. When a plurality of wafers are inserted into the individual slots, the cassette stores the plurality of wafers in predetermined storage positions in a state aligned parallel to each other. According to the BOP, the cassette is placed on the lid such that the upper surface (placing surface) of the lid is parallel to the stored individual wafers.

The BOP allows the cassette to be interlocked with the lid. When the cassette moves down together with the lid, the cassette is removed from the BOP; and when the cassette moves up together with the lid, the cassette is stored in the BOP. Here, in order to prevent misalignment of the cassette while the lid is moving up and down, the direction of the lid moving up and down is set to be perpendicular to the placing surface of the lid; and in order to stably place the cassette, the area of the placing surface of the lid is set to be larger than that of the wafer.

However, if a wafer is moved parallel to other wafers and is slipped out of the cassette in the BOP, the slipped-out wafer may be damaged by colliding with an edge of the opening of the BOP or an internal wall of the main body while the cassette is being removed or stored. For this reason, even the BOP is required to detect whether a wafer is slipped out of the cassette before the cassette is removed or stored.

When the above described light transmission type sensor is used to detect a slip out of a wafer, the light emitting unit and the light receiving unit need to be arranged in the direction perpendicular to the direction of the wafer slipping out, or in the direction perpendicular to the direction of the placing surface of the lid. Further, the light emitting unit and the light receiving unit need to be close as much as possible to wafers stored in the cassette.

In general, installing a light transmission type sensor in a cassette or a lid increases the BOP costs and hence the light transmission type sensor is installed independently of the cassette or the lid. Therefore, the light transmission type sensor does not move up or down as the cassette or the lid moves up and down. The light emitting unit and the light receiving unit are disposed close to wafers. Since the area of the placing surface of the lid is larger than that of the wafer as described above, the light emitting unit and the light receiving unit are found on a moving path of the lid. Therefore, the light transmission type sensor may collide with the lid while the cassette or the lid is moving up and down. For this reason, in order to prevent the light transmission type sensor from colliding with the lid, the light transmission type sensor needs to be away from the moving path of the lid by moving the light transmission type sensor in a direction horizontal to the placing surface of the lid while the cassette or the lid is moving up and down.

### SUMMARY OF THE INVENTION

The present invention provides a substrate positional misalignment detection system capable of detecting positional misalignment of a substrate without moving a detector in the case of using a bottom opening container.

Accordingly, in the present invention, there is provided a substrate positional misalignment detection system for detecting positional misalignment of a substrate when the substrate is loaded or unloaded in a substrate loading/unloading device adapted to unload the substrate from a bottom opening container which stores at least one of the substrates or load the substrate into the bottom opening container, wherein the bottom opening container includes an approximately box-shaped main body having an opening at a bottom thereof, a plate-like lid capable of opening and closing the opening, and a holder capable of being stored in the main body and holding the substrate, the lid places the holder on an upper surface of the lid, the holder holds the substrate parallel to the upper surface of the lid, the substrate loading/unloading device includes a placing unit adapted to place the bottom opening container thereon and a supporting unit adapted to support the lid, the supporting unit moves up and down the lid of the placed bottom opening container together with the holder, the system is provided with a detector including an optical unit provided in the supporting unit and adapted to emit and receive light in an upward/downward direction, a reflection unit provided so as to face the optical unit in a ceiling portion of the main body in the placed bottom opening container and adapted to reflect the emitted light, and a light transmitting unit provided in the lid and adapted to transmit the emitted light and the reflected light in the upward/downward direction, the optical unit, the light transmitting unit, and the reflection unit are aligned linearly in the upward/downward direction, and light emitted by the optical unit is not blocked by the substrate held in a predetermined storage position by the holder.

According to the present invention, the optical unit adapted to emit and receive light in the upward/downward direction is provided in the supporting unit adapted to support the lid and move up and down the lid together with the holder; the reflection unit adapted to reflect the emitted light is provided on the ceiling portion of the main body in the bottom opening container; the light transmitting unit is provided in the lid; and hence, when the lid is moving up and down, the optical unit, the reflection unit, and the light transmitting unit are not found on the lid moving path, thereby eliminating the need to move the detector having the optical unit, the reflection unit, and the light transmitting unit. Specifically, the optical unit, the reflection unit, and the light transmitting unit are aligned linearly in the upward/downward direction and the light emitted by the optical unit is not blocked by the substrate held in the predetermined storage position by the holder. Therefore, when the substrate is not protruded from the holder but is stored in the predetermined storage position without positional misalignment, the optical unit can receive the light reflected by the reflection unit through the light transmitting unit. On the contrary, when the substrate is protruded from the holder and is not stored in the predetermined storage position, causing positional misalignment, the light emitted by the optical unit is blocked by the substrate protruded from the holder, and thus the light emitted by the optical unit does not reach the reflection unit. As a result, the optical unit does not receive the light reflected by the reflection unit. Thereby, it is possible to detect positional misalignment of the substrate.

The present invention can provide a substrate positional misalignment detection system, wherein, in a plan view with respect to the upward/downward direction, the light transmitting unit is not covered by the substrate held in the predetermined storage position by the holder.

According to the present invention, since in a plan view with respect to the upward/downward direction, the light transmitting unit is not blocked by the substrate held in the predetermined storage position by the holder, when the substrate is not protruded from the holder and is stored in the predetermined storage position without positional misalignment, the optical unit can receive the light reflected by the reflection unit through the light transmitting unit. On the contrary, when the substrate is protruded from the holder and is not stored in the predetermined storage position, causing positional misalignment, the light transmitting unit is blocked by the substrate protruded from the holder, and thus the light emitted by the optical unit does not reach the reflection unit. As a result, the optical unit does not receive the light reflected by the reflection unit. Thereby, it is possible to detect positional misalignment of the substrate.

The present invention can provide a substrate positional misalignment detection system, wherein the system detects a timing at which the substrate in course of transmission blocks light emitted by the optical unit.

According to the present invention, the timing is detected at which the substrate in course of transmission blocks the light emitted by the optical unit. The timing differs between the timing at which the substrate without positional misalignment during transfer blocks the light and the timing at which the substrate causing positional misalignment during transfer blocks the light. Accordingly, it is possible to detect positional misalignment of the transferred substrate.

The present invention can provide a substrate positional misalignment detection system, wherein the system detects a timing at which a transfer unit for transferring the substrate blocks light emitted by the optical unit.

According to the present invention, the timing is detected at which the transfer unit for transferring the substrate blocks the light emitted by the optical unit. The timing differs between the timing at which the transfer unit without being shifted away from the transfer path blocks the light and the timing at which the transfer unit being shifted away from the transfer path blocks the light. Accordingly, it is possible to detect positional misalignment of the transfer unit.

The present invention can provide a substrate positional misalignment detection system, wherein the system is provided with a plurality of the detectors, and light beams emitted by each of the optical units of the plurality of the detectors are blocked at the same time by the substrate transferred along a predetermined transfer path.

According to the present invention, when the transferred substrate is not shifted away from the predetermined transfer path, light beams emitted by the plurality of optical units are blocked at the same time by the transferred substrate. On the contrary, when the transferred substrate is shifted away from the predetermined transfer path, light beams emitted by the plurality of optical units are not blocked at the same time by the transferred substrate. As a result, the individual light beam is blocked at a different timing. Thereby, it is possible to detect positional misalignment of the transferred substrate.

The present invention can provide a substrate positional misalignment detection system, wherein the system is provided with a plurality of the detectors, and light beams emitted by each of the optical units of the plurality of the detectors are blocked at the same time by a transfer unit for transferring the substrate along the predetermined transfer path.

According to the present invention, when the transfer unit is not shifted away from the predetermined transfer path, the light beams emitted by the plurality of optical units are blocked at the same time by the transfer unit. On the contrary, when the transfer unit is shifted away from the predetermined transfer path, the light beams emitted by the plurality of optical units are not blocked at the same time by the transfer unit. As a result, the individual light beam is blocked at a different timing. Thereby, it is possible to detect positional misalignment of the transfer unit.

The present invention can provide a substrate positional misalignment detection system, wherein the optical unit is a photoelectric sensor, and the reflection unit is a recursive reflection plate.

According to the present invention, the optical unit is a photoelectric sensor, and the reflection unit is a recursive reflection plate, and hence it is possible to minimize cost. In addition, since there is no need to install an electrical component in the bottom opening container, the bottom opening container can be easily handled.

The present invention can provide a substrate positional misalignment detection system, wherein the substrate loading/unloading device is a component of a semiconductor manufacturing system.

According to the present invention, since the substrate loading/unloading device is the component of the semiconductor manufacturing system, the semiconductor manufacturing system to which the bottom opening container is connected can detect positional misalignment of the substrate without moving the detector.

The features and advantages of the invention will become more apparent from the following detailed description taken in conjunction with the accompanying with drawings.

### BRIEF DESCRIPTION OF THE DRAWINGS

FIG. 1 is a cross-sectional view schematically showing the construction of a substrate receiving device and a container to which a substrate positional misalignment detection system according to a present embodiment is applied.

FIG. 2 is a cross-sectional view showing the positional relation of a cassette, a lid, and wafers in the case where the wafers are stored in predetermined storage positions without positional misalignment in the substrate receiving device and the container as shown in FIG. 1.

FIG. 3 is a plan view showing the positional relation of the cassette, the lid, and the wafers as shown in FIG. 2.

FIG. 4 is a cross-sectional view showing the positional relation of the cassette, the lid, and the wafers in the case where a wafer is shifted from the predetermined storage position, causing positional misalignment in the substrate receiving device and the container as shown in FIG. 1.

FIG. 5 is a plan view showing the positional relation of the cassette, the lid, and the wafers as shown in FIG. 4.

FIG. 6 is a plan view schematically showing the construction of a modification of the substrate positional misalignment detection system according to the present embodiment.

FIG. 7 is a cross-sectional view schematically showing the construction of a substrate receiving device and a container to which a conventional substrate positional misalignment detection system is applied.

### DETAILED DESCRIPTION OF THE PREFERRED EMBODIMENTS

The present invention will now be described in detail with reference to the drawings showing preferred embodiments thereof.

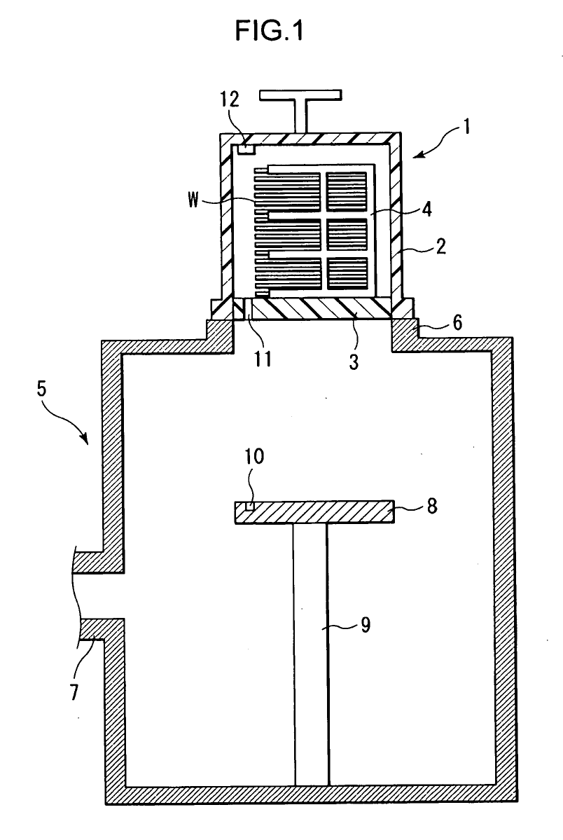

FIG. 1 is a cross-sectional view schematically showing the construction of a substrate receiving device and a container to which a substrate positional misalignment detection system according to a present embodiment is applied.

As showing in FIG. 1, a container 1 (bottom opening container) is a BOP including an approximately box-shaped main body 2 having an opening at a bottom thereof; a plate-like lid 3 capable of opening and closing the opening; and a cassette 4 adapted to be stored in the main body 2 and to hold wafers W. The cassette 4 (holder) is a frame having a plurality of groove-shaped slots (not shown) holding a peripheral edge of a wafer W. A plurality of wafers W are held in a state aligned parallel to each other by inserting the wafers W in the individual slots. In addition, the cassette 4 holds the wafers W such that the individual wafers are parallel to the upper surface (placing surface) of the lid 3 and is placed on the placing surface of the lid 3. The BOP allows the inside of the container 1 to be isolated from the surrounding atmosphere when the lid 3 closes the opening. According to the present embodiment, positions of the wafers W in a state (not slipped out of the slots) where the wafers W are correctly inserted in the slots of the cassette 4 are defined as predetermined storage positions.

An approximately box-shaped cassette module 5 (substrate loading/unloading device) comprises a port 6 (placing portion) adapted to be provided on a ceiling portion of the cassette module 5 and to place the container 1; and a connection portion 7 adapted to be connected to, for example, a transfer module (not shown) through a gate valve (not shown). Further, inside the cassette module 5, there are provided a plate-like supporting unit 8 (supporting unit) adapted to support the lid 3; and a support 9 adapted to support the supporting unit 8. One end of the support 9 supports the supporting unit 8; and the other end thereof is connected to the bottom surface inside the cassette module 5. The supporting unit 8 has an upper surface larger than the wafer W; and the support 9 has a lift mechanism (not shown) so as to make the supporting unit 8 freely move up and down along a direction between the ceiling portion and the bottom portion of the cassette module 5.

The detector comprises a recursive reflection type sensor 10 (optical unit) serving as a photoelectric sensor which is provided in the supporting unit 8 and is adapted to emit and receive light in the upward/downward direction; a recursive reflection plate 12 (reflection unit) which is provided on the ceiling portion of the main body 2 facing the recursive reflection type sensor 10 and is adapted to reflect the emitted light; and a light transmitting window 11 (light transmitting unit) which is provided in the lid 3 and is adapted to transmit the emitted and reflected light in the upward/downward direction. In addition, the recursive reflection type sensor 10, the light transmitting window 11, and the recursive reflection plate 12 are aligned linearly in the upward/downward direction. Further, the recursive reflection type sensor 10 does not protrude from the upper surface of the supporting unit 8; the light transmitting window 11 does not protrude from the placing surface or the bottom surface of the lid 3; and the recursive reflection plate 12 is arranged so as not to collide with the cassette 4 stored in the container 1 or the wafers W held in the predetermined storage positions by the cassette 4.

Moreover, the light transmitting window 11 is placed in a position of the lid 3 which is not covered by the wafers W held in the predetermined storage positions in a plan view with respect to the direction of the supporting unit 8 moving up and down; and is placed in the vicinity of a portion covered by the wafers W held in the predetermined storage positions of the cassette 4 in a direction of the wafers W which can protrude forward (see FIG. 3 described later).

The supporting unit 8 rises by the lift mechanism of the support 9 and the upper surface of the supporting unit 8 comes in contact with the bottom surface of the lid 3. Then, the supporting unit 8 moves down as supporting the lid 3 and the cassette 4 placed on the lid 3 so that the cassette 4 is removed from the container 1, and the lid 3 and the cassette 4 are transferred inside the cassette module 5. Then, the supporting unit 8 supporting the lid 3 and the cassette 4 inside the cassette module 5 rises to transfer the cassette 4 from inside the cassette module 5 to inside the container 1. During this transfer process, the lid 3 and the cassette 4 always move in the direction between the ceiling portion and the bottom portion of the cassette module 5. The wafers W held in the cassette 4 are always perpendicular to the moving direction of the lid 3 and the cassette 4 so as to be parallel to the upper surface of the lid 3.

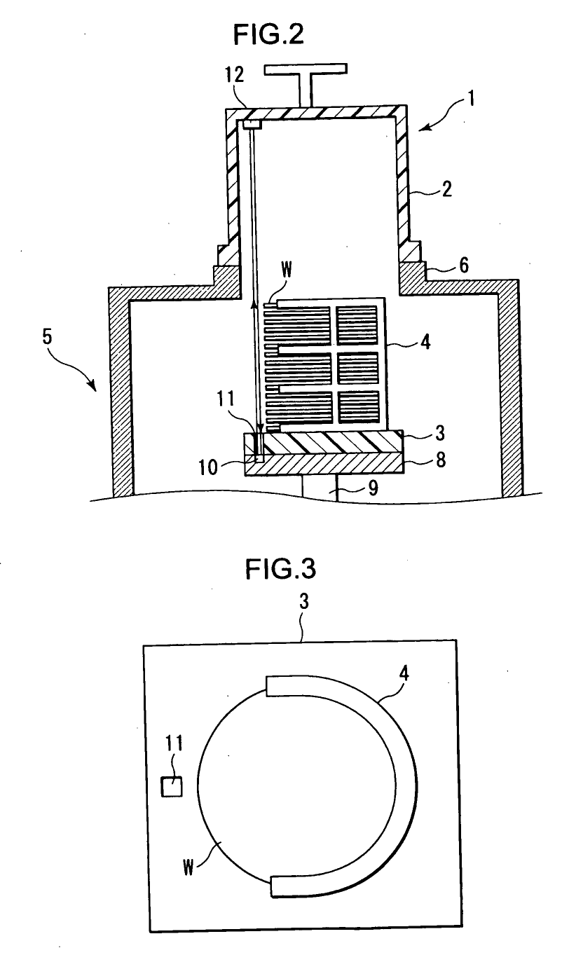

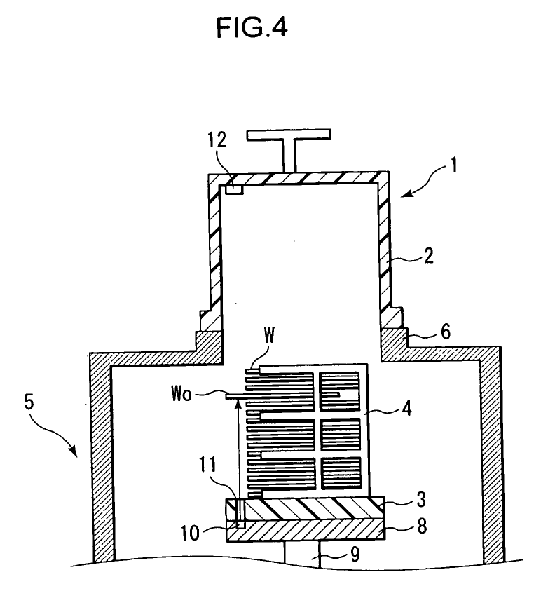

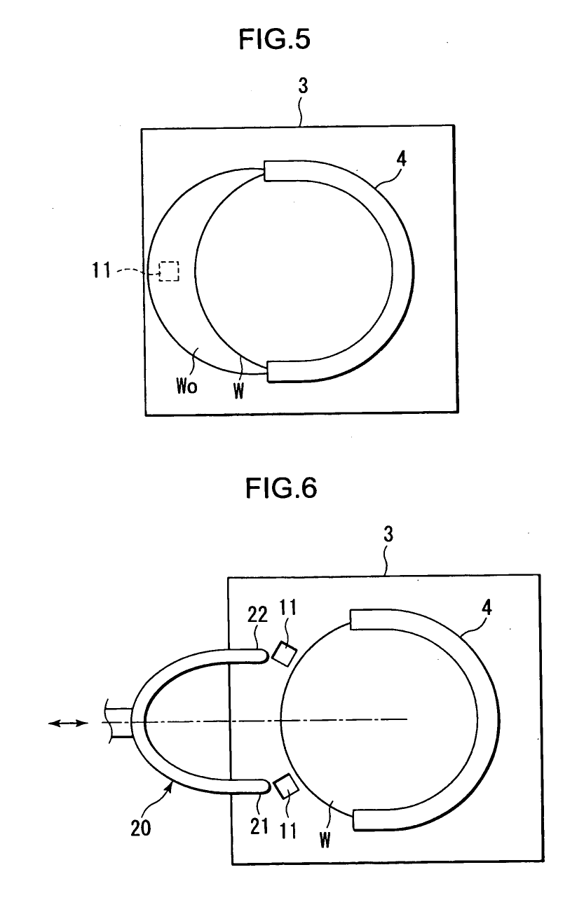

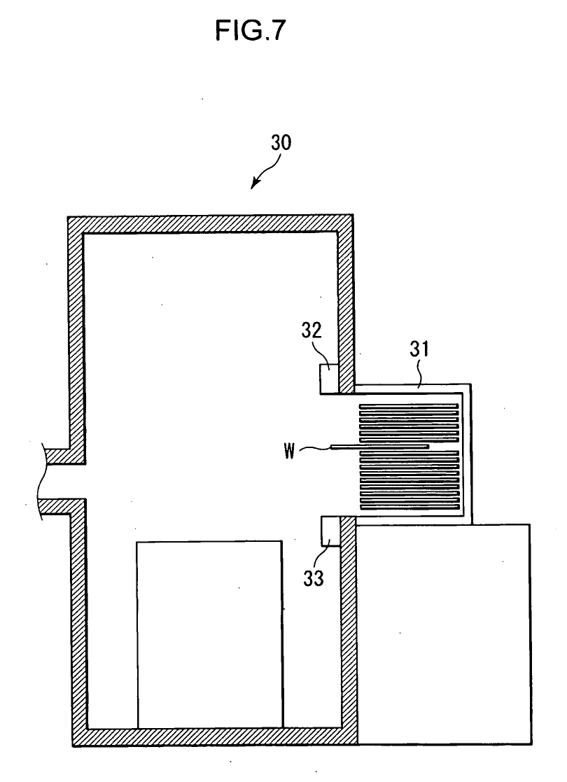

FIG. 2 is a cross-sectional view showing the positional relation of the cassette, the lid, and the wafers in the case where the wafers are stored in the predetermined storage positions without positional misalignment in the substrate receiving device and the container as shown in FIG. 1. FIG. 3 is a plan view showing the positional relation of the cassette, the lid, and the wafers as shown in FIG. 2. FIG. 4 is a cross-sectional view showing the positional relation of the cassette, the lid, and the wafers in the case where a wafer is shifted from the predetermined storage position, causing positional misalignment in the substrate receiving device and the container as shown in FIG. 1. FIG. 5 is a plan view showing the positional relation of the cassette, the lid, and the wafers as shown in FIG. 4.

In the case where the wafers W are stored in predetermined storage positions without positional misalignment, the light transmitting window 11 is not covered by the wafers W in a plan view with respect to the upward/downward direction as shown in FIG. 3, and thus the light emitted by the recursive reflection type sensor 10 toward the ceiling portion reaches the recursive reflection plate 12 through the light transmitting window 11 without being blocked by the wafers W. The reached light is reflected by the recursive reflection plate 12 toward the bottom direction, passes through the light transmitting window 11 and is received by the recursive reflection type sensor 10 (see FIG. 2).

In the case where a wafer Wo is shifted from the predetermined storage position, causing positional misalignment, the light transmitting window 11 is covered by the protruded wafer Wo in a plan view with respect to the upward/downward direction as shown in FIG. 5, and thus the light emitted by the recursive reflection type sensor 10 toward the ceiling portion passes through the light transmitting window 11 but then is blocked by the protruded wafer Wo, and hence does not reach the recursive reflection plate 12. As a result, the emitted light is not reflected by the recursive reflection plate 12 and hence the recursive reflection type sensor 10 does not receive light (see FIG. 4).

As described above, when the wafers W are stored in the predetermined storage positions without positional misalignment, the recursive reflection type sensor 10 which emits light receives the light; but when the wafer Wo is shifted from the predetermined storage position, causing positional misalignment, the recursive reflection type sensor 10 does not receive the light. Therefore, it is possible to detect the presence or absence of positional misalignment of the wafers W depending on the presence or absence of light received.

According to the substrate positional misalignment detection system in accordance with the present embodiment, the recursive reflection type sensor 10 which emits and receive light in the upward/downward direction is provided in the supporting unit 8 which supports the lid 3 and moves up and down with the cassette 4; the recursive reflection plate 12 which reflects the emitted light is provided on the ceiling portion of the main body 2 in the container 1; the light transmitting window 11 is provided in the lid 3; and hence the recursive reflection type sensor 10, the light transmitting window 11, and the recursive reflection plate 12 are not found on the moving path of the lid 3 while the lid 3 is moving up and down. Therefore, a detector having the recursive reflection type sensor 10, the light transmitting window 11, and the recursive reflection plate 12 can be prevented from colliding with the lid 3, thereby eliminating the need to move the detector.

Specifically, the recursive reflection type sensor 10, the light transmitting window 11, and the recursive reflection plate 12 are aligned linearly in the upward/downward direction; since the light emitted by the recursive reflection type sensor 10 is not blocked by the wafers W held in the predetermined storage positions by the cassette 4, when a wafer W is not protruded from the cassette 4 and is stored in the predetermined storage position without positional misalignment, the recursive reflection type sensor 10 can receive the light reflected by the recursive reflection plate 12 through the light transmitting window 11. On the contrary, when the wafer Wo is protruded from the cassette 4 and is shifted from the predetermined storage position, causing positional misalignment, the light emitted by the recursive reflection type sensor 10 is blocked by the protruded wafer Wo and thus the light does not reach the recursive reflection plate 12. As a result, the recursive reflection type sensor 10 does not receive the light reflected by the recursive reflection plate 12. Thereby, it is possible to detect positional misalignment of the wafers W.

It should be noted that according to the substrate positional misalignment detection system in accordance with the present embodiment, the light transmitting window 11 is configured to be relatively small. Therefore, in the above described plan view, when the light emitted by the recursive reflection type sensor 10 is not blocked by the wafers W in the predetermined storage positions, the light transmitting window 11 is not covered by the wafers W; and when the light emitted by the recursive reflection type sensor 10 is blocked by the protruded wafer Wo, the light transmitting window 11 is covered by the wafer Wo.

The detector may be provided in a position where the light emitted by the recursive reflection type sensor 10 is not blocked by the wafers W in the predetermined storage positions, but the light emitted by the recursive reflection type sensor 10 is blocked by the protruded wafer Wo. For example, in the case where the light transmitting window 11 is configured to be relatively large, the light transmitting window 11 does not need to be covered completely by the protruded wafer Wo, but part of the light transmitting window 11 may be covered by the wafer Wo enough to block the light emitted by the recursive reflection type sensor 10.

In addition, in order to prevent the wafers W stored in the cassette 4 from colliding with an inner wall surface of the main body 2 while the supporting unit 8 is moving up and down, for example, the light transmitting window 11 may be provided in a position where the light transmitting window 11 is not covered by the wafers W held in the predetermined storage positions in the above described plan view, but in the vicinity of the outer edge of the lid 3 in a direction of the wafers W protruding. This assures that, in the above described plan view, light is emitted from the vicinity of the outer edge of the lid 3 toward the upward/downward direction, and thus it is possible to detect whether or not the wafers W are protruded from the lid 3. As a result, it is possible to detect in advance the possibility that the wafer W stored in the cassette 4 collides with the inner wall surface of the main body 2 while the supporting unit 8 is moving up and down.

Alternatively, the substrate positional misalignment detection system may detect the timing at which a wafer W in course of transmission blocks the light emitted by the recursive reflection type sensor 10. For example, in the case of detecting the timing at which the wafer W unloaded from the cassette 4 blocks the light emitted by the recursive reflection type sensor 10, the timing differs between the timing at which the wafer W without positional misalignment during transfer blocks the light and the timing at which the wafer W causing positional misalignment during transfer blocks the light. Accordingly, it is possible to detect positional misalignment of the transferred wafer W.

Alternatively, the substrate positional misalignment detection system may detect the timing at which, a transfer unit transferring the wafer W, for example, the pick 20 described later blocks the light emitted by the recursive reflection type sensor 10. For example, in the case where the timing is detected at which the transfer unit coming close to the cassette 4 to unload the wafer W from the cassette 4 blocks the light emitted by the recursive reflection type sensor 10, the timing differs between the timing at which the transfer unit without positional misalignment from the transfer path blocks the light and the timing at which the transfer unit causing positional misalignment from the transfer path blocks the light. Accordingly, it is possible to detect positional misalignment of the transfer unit.

It should be noted that the number of detectors provided in the substrate positional misalignment detection system is not limited to one. For example, when the wafer W is unloaded from the cassette 4 by the transfer unit, as shown in FIG. 6, in the above described plan view, two detectors (light transmitting windows 11) may be perpendicular to the direction in which the pick 20 (transfer unit) unloads the wafer W and may have an equal distance from the center line (shown by a dashed-dotted line in the FIG. 6) of the wafer W transfer path.

In this case, when the pick 20 unloads the wafer W from the cassette 4 as holding the wafer W in a normal position, or when the wafer W is transferred along a predetermined transfer path, the individual light beams emitted by the two recursive reflection type sensors 10 are blocked at the same time by the transferred wafers W, and hence the two recursive reflection type sensors 10 stop receiving the light at the same time. On the contrary, when the pick 20 unloads the wafer W from the cassette 4 without holding the wafer W in a normal position, or when the wafer W is not transferred along a predetermined transfer path, the individual light beams emitted by the two recursive reflection type sensors 10 are not blocked at the same time by the transferred wafers W, and hence the two recursive reflection type sensors 10 stop receiving the light at the different timings. Therefore, it is possible to detect whether or not the wafer W is transferred along the predetermined transfer path by comparing the timings at which the two detectors receive light, and thereby it is possible to detect whether or not the pick 20 holds the wafer W in a normal position.

In addition, when the pick 20 does not hold the wafer W, positional misalignment of the pick 20 may be detected by comparing whether or not the individual light beams emitted by the two recursive reflection type sensors 10 are blocked at the same time by end portions 21 and 22 of the pick 20.

In addition, the detector in accordance with the present embodiment is configured only with the recursive reflection type sensor 10, the light transmitting window 11, and the recursive reflection plate 12 and hence it is possible to minimize cost of manufacturing the substrate positional misalignment detection system. Further, the BOP has only the recursive reflection plate 12 and the light transmitting window 11, and thus there is no need to install an electrical component such as a photoelectric sensor. Accordingly, it is easy to handle the BOP such as when cleaning the BOP.

It should be noted that according to the above described individual present embodiment, the substrate is a semiconductor wafer, but the substrate is not limited to this, but, for example, a glass substrate such as an LCD (Liquid Crystal Display) and an FPD (Flat Panel Display) may be used.

What is claimed is:

1. A substrate positional misalignment detection system for detecting positional misalignment of a substrate when the substrate is loaded or unloaded in a substrate loading/unloading device adapted to unload the substrate from a bottom opening container which stores at least one of the substrates or load the substrate into the bottom opening container, wherein
the bottom opening container includes an approximately box-shaped main body having an opening at a bottom thereof, a plate-like lid capable of opening and closing the opening, and a holder capable of being stored in the main body and holding the substrate; the lid places the holder on an upper surface of the lid; the holder holds the substrate parallel to the upper surface of the lid;
the substrate loading/unloading device includes a placing unit adapted to place the bottom opening container thereon and a supporting unit adapted to support the lid; the supporting unit moves up and down the lid of the placed bottom opening container together with the holder;
the system is provided with a detector including an optical unit provided in the supporting unit and adapted to emit and receive light in an upward/downward direction; a reflection unit provided so as to face the optical unit in a ceiling portion of the main body in the placed bottom opening container and adapted to reflect the emitted light; and a light transmitting unit provided in the lid and adapted to transmit the emitted light and the reflected light in the upward/downward direction;
the optical unit, the light transmitting unit, and the reflection unit are aligned linearly in the upward/downward direction; and
light emitted by the optical unit is not blocked by the substrate held in a predetermined storage position by the holder.

2. The substrate positional misalignment detection system as claimed in claim 1, wherein, in a plan view with respect to the upward/downward direction, the light transmitting unit is not covered by the substrate held in the predetermined storage position by the holder.

3. The substrate positional misalignment detection system as claimed in claim 1, wherein the system detects a timing at which the substrate in course of transmission blocks light emitted by the optical unit.

4. The substrate positional misalignment detection system as claimed in claim 1, wherein the system detects a timing at which a transfer unit for transferring the substrate blocks light emitted by the optical unit.

5. The substrate positional misalignment detection system as claimed in claim 1, wherein the system is provided with a plurality of said detectors; and
light beams emitted by each of the optical units of the plurality of said detectors are blocked at the same time by the substrate transferred along a predetermined transfer path.

6. The substrate positional misalignment detection system as claimed in claim 1, wherein the system is provided with a plurality of said detectors; and
light beams emitted by each of the optical units of the plurality of said detectors are blocked at the same time by a transfer unit for transferring the substrate along the predetermined transfer path.

7. The substrate positional misalignment detection system as claimed in claim 1, wherein the optical unit is a photoelectric sensor, and the reflection unit is a recursive reflection plate.

8. The substrate positional misalignment detection system as claimed in claim 1, wherein the substrate loading/unloading device is a component of a semiconductor manufacturing system.
